(19) United States
(12) Patent Application Publication
(10) Pub. No.: US 2020/0014216 A1
(43) Pub. Date: Jan. 9, 2020

(54) WIRELESS POWER SYSTEM HAVING SELF-VOLTAGE-CONTROLLED RECTIFICATION APPARATUS, AND COMMUNICATION METHOD THEREOF

(71) Applicant: MAPS, INC., Seoul (KR)

(72) Inventors: Jong Tae HWANG, Seoul (KR); Dong Su LEE, Dongducheon-si (KR); Jong Hoon LEE, Seoul (KR); Hyun Ick SHIN, Seoul (KR); Joon RHEE, Seoul (KR)

(73) Assignee: MAPS, INC., Seoul (KR)

(21) Appl. No.: 16/490,188

(22) PCT Filed: Feb. 9, 2018
(86) PCT No.: PCT/KR2018/002084

§ 371 Date: Aug. 30, 2019

(30) Foreign Application Priority Data
Mar. 13, 2017 (KR) 10-2017-0031328
May 15, 2017 (KR) 10-2017-0060130

(51) Int. Cl. H02J 5/00; H02J 50/12; H02M 7/04; H03J 1/00

(52) U.S. Cl. CPC H02J 5/005; H03J 1/00; H02M 7/04; H02J 50/12

(57) ABSTRACT

Disclosed are a wireless power system including a self-regulation rectifier and a communication method thereof. The wireless power system according to an embodiment includes a reception resonator which magnetically resonates with a wireless power transfer unit through a reception antenna, a self-regulation rectifier which rectifies a power signal in a form of an alternating current (AC) received from the reception resonator into a power signal in a form of a direct current (DC) and self-regulates a rectifier output voltage without a separate power converter, and a frequency adjuster which changes a resonance frequency of the reception resonator for in-band communication with the wireless power transfer unit, wherein a reception antenna current is changed according to a change in the resonant frequency, and the reception resonator transmits a communication signal to the wireless power transfer unit through induction of the changed reception antenna current.

### TECHNICAL FIELD

The present invention relates to wireless power transmission and control technology, and more specifically, to communication technology between a power transfer unit and a power receiving unit which transmit and receive wireless power.

### BACKGROUND ART

Wireless power systems include a power transfer unit (hereinafter, referred to as PTU) and a power receiving unit (hereinafter, referred to as PRU) which wirelessly transmit and receive power. The PRU receives power using a resonator including an inductor L and a capacitor C. In this case, an alternating current (AC) having the same frequency as power transmitted by the PTU flows as power of the resonator. Generally, a final output signal is generated in the form of a stable DC signal and supplied to a load, and thus, there is a need for a rectifier. The rectifier converts an AC signal into a DC signal that is not regulated. A power converter converts the DC signal into a precise DC voltage signal and supplies the DC voltage signal to a load. The PRU has a two-stage structure regardless of type of a power converter being provided, and power transmission efficiency of the PRU is determined by multiplying efficiency of the rectifier and efficiency of the power converter. Accordingly, it is difficult to achieve high efficiency when the power converter has a multi-stage structure.

### DISCLOSURE

### Technical Problem

The present invention is directed to providing a wireless power system having self-regulation rectifier in which stable output power may be generated only using a rectifier and a resonator without a separate power converter, thereby improving power transmission efficiency, and a communication method of the wireless power system.

### Technical Solution

According to an embodiment of the present invention, a wireless power system includes a reception resonator which magnetically resonates with a wireless power transfer unit through a reception antenna, a self-regulation rectifier which rectifies a power signal in a form of an alternating current (AC) received from the reception resonator into a power signal in a form of a direct current (DC) using a rectifier and self-regulates a rectifier output voltage without a separate power converter, and a frequency adjuster which changes a resonance frequency of the reception resonator for in-band communication with the wireless power transfer unit, wherein a reception antenna current is changed according to a change in the resonant frequency, and the reception resonator transmits a communication signal to the wireless power transfer unit through induction of the changed reception antenna current.

The frequency adjuster may change the resonance frequency of the reception resonator according to the rectifier output voltage and a rectifier output current controlled by the self-regulation rectifier. The frequency adjuster may change the resonance frequency of the reception resonator according to a communication command for exchanging information with the wireless power transfer unit.

The communication signal may include information for adjusting output power of the wireless power transfer unit and other information for in-band communication with the wireless power transfer unit.

The frequency adjuster may include a capacitor which is connected to the reception antenna of the reception resonator and changes the resonance frequency of the reception resonator and a communication switching element which is connected in series to the capacitor, receives a control signal, performs switching operation, and controls a change in the reception antenna current. The communication switching element may include a first output terminal connected to the capacitor, a second output terminal connected to a ground, and an input terminal receiving a control signal for in-band communication. A resonance frequency of the reception antenna and a capacitor of the reception resonator when the communication switching element is turned on may be different from a resonance frequency of the reception antenna and a resonance capacitor network of the reception resonator when the communication switching element is turned off.

The wireless power system may further include a communication controller which generates a control signal for switching the communication switching element according to at least one of the rectifier output voltage, a rectifier output current, and information to be exchanged with the wireless power transfer unit and transmits the generated control signal to the communication switching element.

The self-regulation rectifier may include a rectifier which converts AC power received from the reception resonator into DC power and supplies the rectifier output voltage to a load and a low voltage switching element which includes output terminals connected to a rectifier input terminal and a ground and an output terminal receiving a control signal generated according to the rectifier output voltage.

When the rectifier output voltage is increased, the low voltage switching element may receive a control signal for turning the low voltage switching element on, block the rectifier from supplying power to the load, and decrease the rectifier output voltage, and when the rectifier output voltage is decreased, the low voltage switching element may receive a control signal for turning the low voltage switching element off, allow the rectifier to supply power to the load, and increase the rectifier output voltage.

The wireless power system may further include a transmission antenna which is magnetically coupled with the reception antenna and in which a current variation of the reception antenna is induced thereto, a current variation detector which detects a variation of a power supply current supplied from a power supply to a power amplifier according to induction of the current variation and detects a digital communication signal from the detected current variation, and a power controller which controls output power of the power amplifier according to the digital communication signal detected by the current variation detector;

According to another embodiment of the present invention, a communication method of a wireless power system includes receiving, by a wireless power receiving unit, a power signal in a form of an AC through a reception antenna of a reception resonator and rectifying the power signal in the form of the AC into a power signal in a form of a DC through a rectifier, wherein a rectifier output voltage is self-regulated without a separate power converter; changing, by the wireless power receiving unit, a resonance frequency of the reception resonator for in-band communication with a wireless power transfer unit to change a reception antenna current of the reception resonator; and transmitting, by the wireless power receiving unit, a communication signal to the wireless power transfer unit through induction of the changed reception antenna current.

The changing of the reception antenna current of the reception resonator may include receiving, by a communication switching element, a control signal for the in-band communication to be turned on and changing a resonant frequency of the reception antenna through a capacitor connected to the communication switching element which is turned on. The control signal for the in-band communication may be generated according to at least one of the rectifier output voltage, a rectifier output current, and information to be exchanged with the wireless power transfer unit.

An in-band communication method in the wireless power system may further include inducing, by the wireless power transfer unit, a current variation from the reception antenna through a transmission antenna magnetically coupled with the reception antenna, detecting, by the wireless power transfer unit, a variation of a power supply current supplied from a power supply to a power amplifier according to induction of the current variation and detecting a digital communication signal from the detected variation of the power supply current, and controlling, by the wireless power transfer unit, output power of the power amplifier according to the detected digital communication signal.

### Advantageous Effects

According to an embodiment, a power receiving unit (PRU) can generate a stable output voltage using a self-regulation rectifier (SRR). In this case, since a switching element and a reception antenna of the SRR are separated, the switching element can be implemented at a low voltage. In addition, a current flowing when the switching element is turned on is smaller than an antenna current, thereby solving a decrease in efficiency and a heat generation problem caused when all of the antenna current flows through the switching element absorbing the antenna current. Furthermore, since the antenna current is maintained to be constant, an electromagnetic interference (EMI) is also not influenced by a driving frequency of the switching element, thereby facilitating a design of an EMI filter. In addition, in a wireless power system including an SRR, a PRU can transmit control information to a power transfer unit (PTU) through communication, in particular, in-band communication, thereby controlling output power of the PTU.

### DESCRIPTION OF DRAWINGS

FIG. 1 is a structural diagram illustrating a general power receiving unit (PRU).

FIG. 2 is a structural diagram illustrating a PRU which receives power by controlling an active element.

FIG. 3 is a graph showing an amount of change in antenna current when an output voltage is controlled using a switching operation in a structure of FIG. 2.

FIG. 4 is a structural diagram illustrating a receiving unit using a resonant frequency control method using a clocking signal.

FIG. 5 is a structural diagram illustrating a PRU including a self-regulation rectifier (SRR) so as to solve problems of a structure of the PRU described above with reference to FIGS. 2 to 4.

FIGS. 6 and 7 are structural diagrams illustrating the PRU in a state in which a switching element (M1) of FIG. 5 is turned off to increase an output voltage (VOUT) (power is supplied to a load).

FIGS. 8 and 9 are structural diagrams illustrating the PRU in a state in which the switching element (M1) of FIG. 5 is turned on to decrease the output voltage (VOUT) (power is not supplied to the load).

FIG. 10 is a structural view illustrating a PRU further including a controller in a structure of FIG. 5.

FIG. 11 illustrates simulation waveform diagrams showing that an output voltage (VOUT) is controlled when a load current is changed from 0 mA to 200 mA in a structure of FIG. 10.

FIG. 12 is a waveform diagram illustrating a driving waveform of a switching element (M1) in a structure of FIG. 10.

FIG. 13 is a structural diagram illustrating a PRU including an SRR having a parallel structure according to an embodiment of the present invention.

FIG. 14 is a structural diagram illustrating a wireless power system for transmitting and receiving information using an in-band communication method applied to a conventional inductive wireless power transmission system such as a Qi or PMA type.

FIG. 15 illustrates operation waveform diagrams of the wireless power system in which information is exchanged through the in-band communication method of FIG. 14.

FIG. 16 is a structural diagram illustrating a wireless power system performing in-band communication when an SRR is used according to an embodiment of the present invention.

FIG. 17 illustrates operational waveform diagrams of the wireless power system including the SRR of FIG. 16 according to the embodiment of the present invention.

FIG. 18 is a flowchart illustrating an in-band communication method of a wireless power system according to an embodiment of the present invention.

### MODES OF THE INVENTION

Advantages and features of the present invention and methods for accomplishing the same will be more clearly understood from embodiments described below with reference to the accompanying drawings. However, the present invention is not limited to the following embodiments described below but may be implemented in other forms. The embodiments are provided to complete the disclosure of the present invention and to allow those having ordinary skill in the art to fully understand the scope of the present invention. The present invention is defined by the category of the claims. Like reference numerals generally denote like elements throughout the present specification.

In the following description of the embodiments of the present invention, when a detailed description of a relevant known function or configuration is determined to unnecessarily obscure the gist of the present invention, the detailed description will be omitted. Also, terms used herein are defined in consideration of the functions of the present invention and may be changed depending on a user, the intent of an operator, or a custom. Accordingly, the terms should be defined on the basis of the following overall description of this specification. Hereinafter, the embodiments of the present invention will be described in detail with reference to the accompanying drawings.

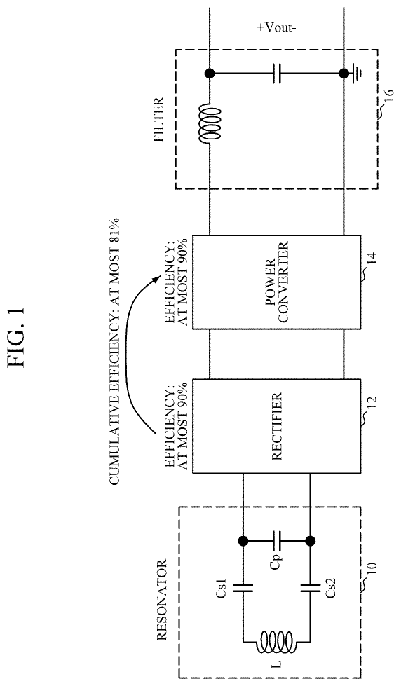

FIG. 1 is a structural diagram illustrating a general power receiving unit (PRU).

Referring to FIG. 1, the PRU includes a resonator 10, a rectifier 12, a power converter 14, and a filter 16.

The PRU receives wireless energy from a power transfer unit (PTU) through a resonator 10 including an inductor L and capacitors Cs1 and Cs2. In this case, an alternating current (AC) having the same frequency as a frequency transmitted by the PTU flows in the resonator 10. The rectifier 12 and the power converter 14 generate a stable direct current (DC) signal as final output from an AC signal and supply power to a load. To this end, the rectifier 12 converts the AC signal into a DC signal that is not regulated. The power converter 14 converts the DC signal into a precise DC voltage Vout and supplies the DC voltage Vout to the load. The power converter 14 is not limited to a specific type and may be, for example, a buck type, a boost type, or a linear type.

The PRU has a two-stage structure regardless of type of the power converter 14 being provided, and power transmission efficiency of the PRU is determined by multiplying efficiency of the rectifier 12 and efficiency of the power converter 14. For example, as shown in FIG. 1, when the efficiency of the rectifier 12 is at most 90% and the efficiency of the power converter 14 is at most 90%, cumulative efficiency is reduced to at most 81%. Accordingly, it is difficult to satisfy high efficiency when the power converter 14 is configured as a multi-stage.

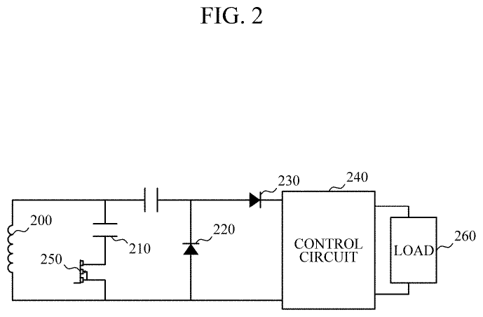

FIG. 2 is a structural diagram illustrating a PRU which receives power by controlling an active element.

Referring to FIG. 2, the PRU receives energy through a resonator including an inductor 200 and a capacitor 210. The inductor 200 has an equivalent inductance of an antenna. Next, a rectifier including diodes 220 and 230 converts an AC signal into a DC signal and then supplies energy to a load 260. In this case, a control circuit 240 controls an active element 250 to control a voltage supplied to the load 260. Unlike the method described above with reference to FIG. 1, such a method does not require a separate power converter, and a rectifier output voltage may be controlled using one stage rectifier. However, when the active element 250 is operated as a resistor, efficiency may not be high. In addition, an antenna voltage is proportional to receiving sensitivity and power of a PTU. In some cases, a voltage close to a voltage of several hundred volts may be generated. Therefore, the active element 250 connected to an antenna should have a high breakdown voltage to withstand the generated voltage.

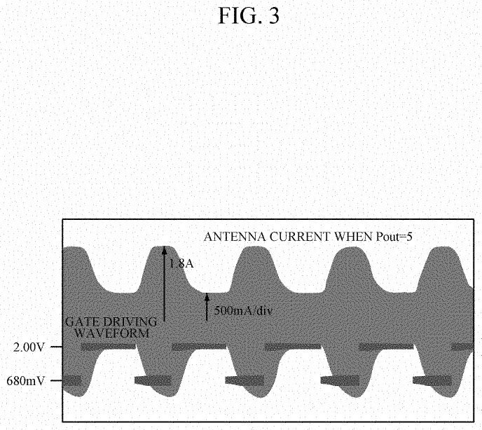

FIG. 3 is a graph showing an amount of change in antenna current when an output voltage is controlled using a switching operation in the structure of FIG. 2.

Referring to FIG. 3, since a circuit of FIG. 2 uses a metal-oxide field-effect transistor (MOSFET) element as a linear element, a great deal of heat may be generated by power consumption. Thus, a pulse may be applied for gate driving, thereby controlling the MOSFET element so as to be operated as a switching element. In this case, heat generation of the MOSFET element may be reduced, but the antenna current may be modulated as shown in FIG. 3.

For example, in a state in which an output voltage is controlled such that a load consumes a power of 5 W, the MOSFET is switch-controlled using a gate driving waveform to maintain the output voltage at a constant voltage. When the MOSFET is turned on, the capacitor 210 of FIG. 2 changes a resonant frequency, and thus, the antenna current is decreased. That is, when a current is supplied to the load, the antenna current is increased, and when the MOSFET is turned on to lower an output voltage, the antenna current is decreased. The antenna current appears to be modulated by the gate driving waveform. Such a change in current waveform means that output power generated by a PTU is changed. Therefore, operating conditions of a PTU circuit may be changed, which may affect a stable operation. Since a noise frequency is modulated and generated by the gate driving waveform, an electromagnetic interference (EMI) may be influenced by the gate driving waveform, which may cause a difficulty in implementing a circuit to suppress the EMI.

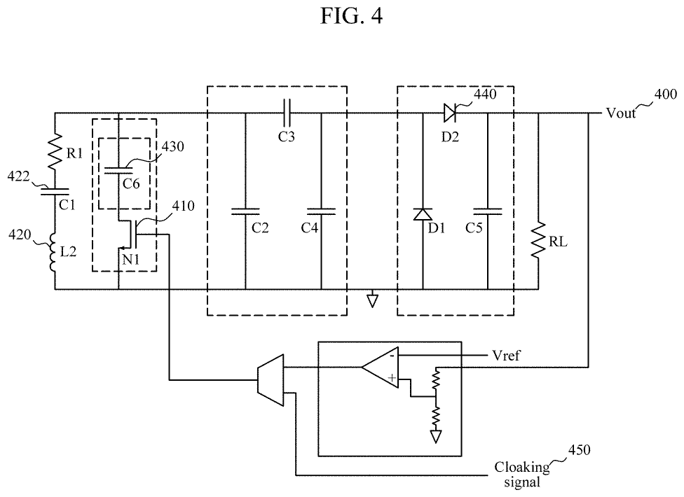

FIG. 4 is a structural diagram illustrating a receiving unit using a resonant frequency control method using a clocking signal.

Referring to FIG. 4, in order for an output voltage Vout 400 to reach a desired voltage, the output voltage Vout 400 is adjusted by controlling a switching element N1 410 using a clocking signal 450. A method of FIG. 4 is similar to that of FIG. 2, but the switching element N1 410 is positioned at a rear end of a resonator including an inductor L2 420 and a capacitor C1 422. A control method may be the same as that of FIG. 2.

When the switching element N1 410 is turned on, all of a resonator current flows through the switching element N1 410, and thus, power consumption of the switching element N1 410 may be a problem as in the case of FIG. 2. In addition, according to the method, when the switching element N1 410 is turned on, capacitors C1 422 and C6 430 serve to change a resonant frequency. When capacitance of the capacitor C6 430 is considerably greater than capacitance of the capacitor C1 422, the resonant frequency is not changed very much. Therefore, a current flowing through the switching element N1 410 may be very large.

When the capacitance of the capacitor C6 430 is decreased, a resonance frequency is increased to decrease a resonance current, but a voltage across the capacitor C6 430 may be increased. In this case, a diode D2 440 of a rectifier may be turned on to supply a current to a load. When the switching element N1 410 is turned on, it is intended to lower an output voltage by absorbing an antenna current and preventing the diode D2 440 from being turned on. However, when the capacitance of the capacitor C6 430 is too small, such a function may not be performed, and thus, the output voltage may not be regulated.

As described above with reference to FIGS. 2 to 4, controlling output using a one stage rectifier may be suitable in terms of efficiency, but in order to exhibit performance that is suitable for actual use, there are some problems to be solved as follows.

(1) Use of Low Voltage Element: in order to reduce a price and manufacture a PRU through a low voltage semiconductor process, a low voltage element should be able to be used.

(2) Problem of Antenna Current Modulation: even when output is controlled, an antenna current should be maintained to be relatively constant to stabilize operation of a PTU and reduce a problem that a control signal acts on an EMI.

(3) Power Consumption: power consumption of an element used to control an output voltage should be lowered to increase efficiency and suppress heat generation.

In order to solve the above-described three problems, the present invention proposes a structure of a PRU.

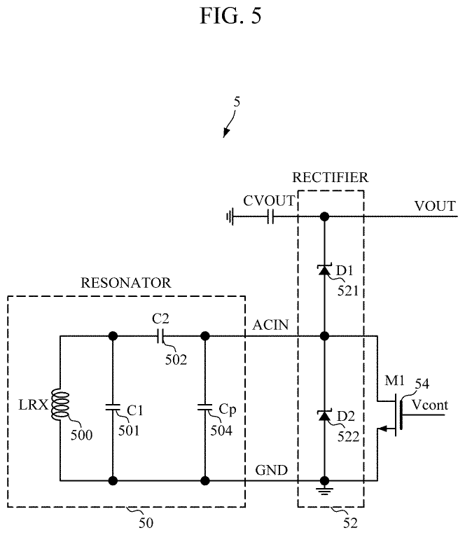

FIG. 5 is a structural diagram illustrating a PRU including a self-regulation rectifier (SRR) so as to solve the problems of the structure of the PRU described above with reference to FIGS. 2 to 4.

Referring to FIG. 5, a PRU 5 includes a resonator 50, a rectifier 52, and a switching element M1 54.

The resonator 50 includes an inductor LRX 500 and capacitors C1 501, C2 502, and Cp 504. The inductor LRX 500 is an inductor model for an antenna for receiving power, and the capacitors C1 501 and C2 502 are capacitors which determine a resonant frequency of the PRU 5. The capacitor C2 502 may be connected in series to the inductor LRX 500, and the capacitor C1 501 may be connected in series to the inductor LRX 500 and in parallel to the capacitor C2 502. The capacitor C1 501 is a capacitor which directly returns a current to the inductor LRX 500, and the capacitor C2 502 is a capacitor which returns a current through the rectifier 52 to supply the current to a load. The capacitor Cp 504 is not directly related to wireless power transmission but prevents parasitic oscillation at a rectifier input terminal ACIN.

The rectifier 52 may convert AC input to a DC and may be a half-wave rectifier including diodes D1 521 and D2 522 as shown in FIG. 5.

The switching element M1 54 controls a rectifier output voltage VOUT. Typically, when a control voltage Vcont greater than or equal to a threshold voltage is applied to turn the switching element M1 54 on, the output voltage VOUT may be lowered. Therefore, output may be controlled without a separate power converter, and thus, efficiency may be improved.

The switching element M1 54 according to an embodiment may include a first output terminal connected to the rectifier input terminal ACIN, a second output terminal connected to a ground, and an input terminal to which the control signal Vcont for self-regulating the rectifier output voltage VOUT is applied. When the switching element M1 54 is turned on, an antenna current is distributed so that a current flowing through the switching element M1 54 is smaller than the antenna current.

The rectifier output voltage VOUT is maintained to be constant by the switching element M1 54. For example, when the rectifier output voltage VOUT is increased, the switching element M1 54 receives a control signal that turns the switching element M1 54 on and blocks the rectifier 52 from supplying power to the load, thereby decreasing the output voltage VOUT. On the contrary, when the rectifier output voltage VOUT is decreased, the switching element M1 54 receives a control signal that turns the switching element M1 54 off and allows the rectifier 52 to supply power to the load, thereby increasing the output voltage VOUT. Accordingly, the rectifier output voltage VOUT is maintained to be constant.

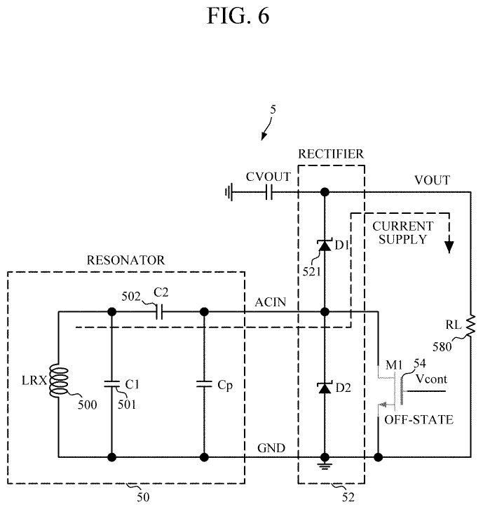

According to the proposed structure of the SRR, since the switching element 54 configured to control the rectifier output voltage VOUT is separated from a reception antenna, the switching element 54 may be implemented at a low voltage. In addition, a current flowing when the low voltage switching element 54 is turned on is smaller than the antenna current, thereby solving a decrease in efficiency and a heat generation problem caused when all of the antenna current flows through the switching element 54 absorbing the antenna current. Furthermore, since the antenna current is maintained to be constant, an EMI is also not influenced by a driving frequency of the switching element 54, thereby facilitating a design of an EMI filter. Hereinafter, the output voltage VOUT will be described with reference to FIGS. 6 to 9 as being constantly adjusted through self-regulation in the structure of the PRU of FIG. 5.

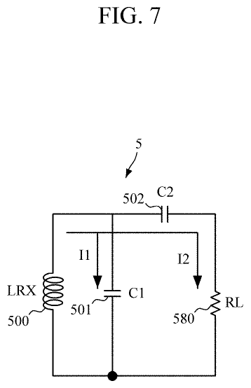

FIGS. 6 and 7 are structural diagrams illustrating the PRU in a state in which the switching element M1 of FIG. 5 is turned off to increase the output voltage VOUT (power is supplied to the load).

When the output voltage VOUT is in a state of being a desired voltage or lower than the desired voltage and the switching element M1 54 is turned off, the diode D1 521 conducts a current and transmits power to the load (see FIG. 6). An equivalent circuit of FIG. 6 is as shown in FIG. 7.

Referring to FIGS. 6 and 7, an antenna current is divided into a current II and a current I2 which flow through the capacitors C1 501 and C2 502, respectively. When resistance of a load resistor RL 580 is not large, that is, high power consumption is required, a resonance frequency is approximately determined according to Expression 1.

$$f = \frac{1}{2 π \sqrt{LRX \times ( C 1 + C 2 )}} . \qquad [ Expression 1 ]$$

When a receiving unit is manufactured for an alliance for wireless power (A4WP) PTU using a frequency 6.78 MHz, an A4WP receiving unit determines the inductors LRX 500 and the capacitors C1 501 and C2 502 such that a resonant frequency becomes 6.78 MHz.

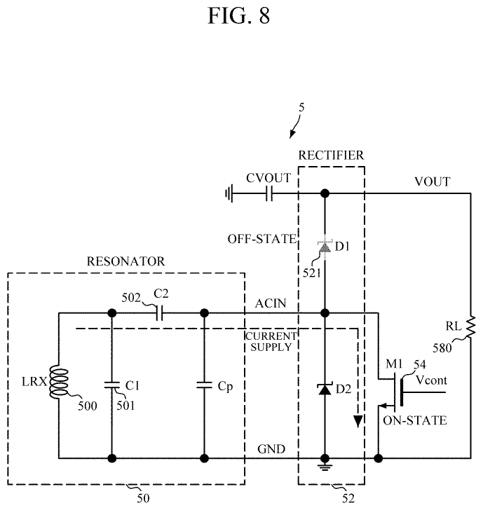

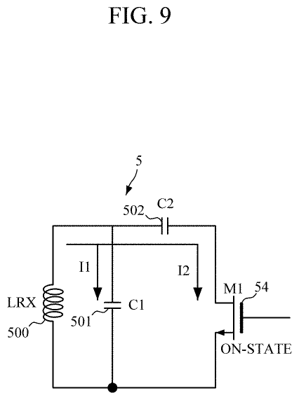

FIGS. 8 and 9 are structural diagrams illustrating the PRU in a state in which the switching element M1 of FIG. 5 is turned on to decrease the output voltage VOUT (power is not supplied to the load).

When the output voltage VOUT is higher than the desired voltage, as shown in FIG. 8, the switching element M1 54 is turned on to block power from being supplied as output. Therefore, since the diode D1 521 is turned off, the load is not electrically connected. In this case, an equivalent circuit is as shown in FIG. 9.

When the switching element M1 54 is turned on, a resistance component may be set to be very small. Thus, assuming that equivalent resistance of the switching element M1 54 is very small, a resonance frequency is the same as that of Expression 1. Therefore, in any case, a resonance frequency does not change significantly from the standpoint of the antenna LRX 500.

The resistor RL 580 is shown in FIGS. 6 and 7 as being connected in series to the capacitor C2 502. However, since a state in which the diode D1 521 is turned on corresponds to a state in which a load requires power, it may not be considered that the resistor RL 580 has a very large resistance value. When the load does not consume power, it may be considered that the resistance of the resistor RL 580 is very large. In this case, since the output voltage VOUT is increased, the switching element M1 54 is turned on. Therefore, in this case, as shown in FIGS. 8 and 9, the PRU is operated, and thus, in any case, a resistance component connected in series to the capacitor C2 502 is not large. That is, in both cases, since states of the resonator are almost similar to each other, an antenna current is maintained to be almost constant. Therefore, whether the switching element M1 54 is turned on or off, a PTU is in a condition of being stably operated. As shown in FIG. 3, since an antenna current does not change significantly, an EMI is also not influenced by a driving frequency of the switching element M1 54, thereby facilitating a design of an EMI filter.

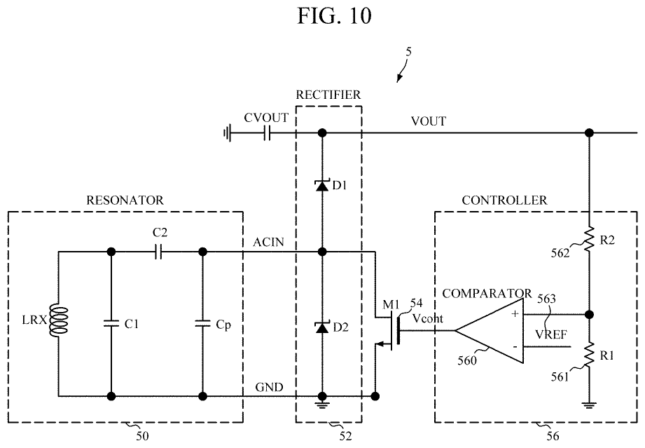

FIG. 10 is a structural view illustrating a PRU further including a controller in the structure of FIG. 5.

Referring to FIG. 10, a controller 56 includes a comparator 560, resistors R1 561 and R2 562, and a reference voltage VREF 563 which are for sensing an output voltage VOUT. When a condition of VOUT×R1/(R1+R2)>VREF is satisfied, output Vcont of the comparator 560 becomes high and a switching element M1 54 is turned on to lower the output voltage VOUT. Therefore, the output voltage VOUT is controlled to be (1+R2/R1)×VREF.

Since only brief operation of a configuration of the comparator 560 has been described, it is possible to provide a circuit which allows the switching element M1 54 to be zero-voltage-switched or a circuit which has an additional function of preventing the comparator 560 from being operated too frequently by adding hysteresis to the comparator 560.

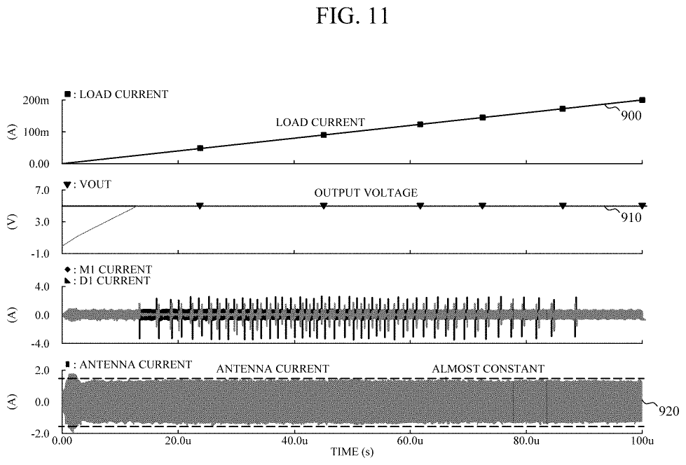

FIG. 11 is a simulation waveform diagram illustrating that an output voltage VOUT is controlled when a load current is changed from 0 mA to 200 mA in the structure of FIG. 10.

Referring to FIGS. 10 and 11, a simulation was performed in such a manner that in a state in which the resonator was set to be operated at a frequency of 6.78 MHz, the controller 56 was set to regulate an output voltage VOUT 910 to 5 V. As shown in FIG. 11, it can be confirmed that the output voltage VOUT 910 is well controlled at 5 V even when a load current 900 is changed up to 200 mA. The initial output voltage VOUT 910 is low because a rectifier capacitor CVOUT is discharged and thus is in a state of being charged. It can be seen that an antenna current 920 is maintained to be almost constant even when the load current is changed.

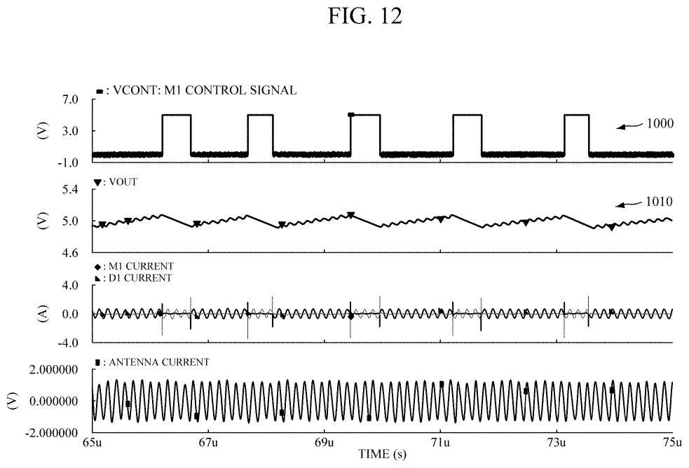

FIG. 12 is a waveform diagram illustrating a driving waveform of the switching element M1 in the structure of FIG. 10.

Referring to FIGS. 10 and 12, when the switching element M1 is turned on by a switching control signal 1000 with a high level, an output voltage VOUT 1010 is decreased. When the output voltage VOUT 1010 is decreased, the switching element M1 is turned off by the switching control signal 1000 with a low level to increase output voltage VOUT 1010 again.

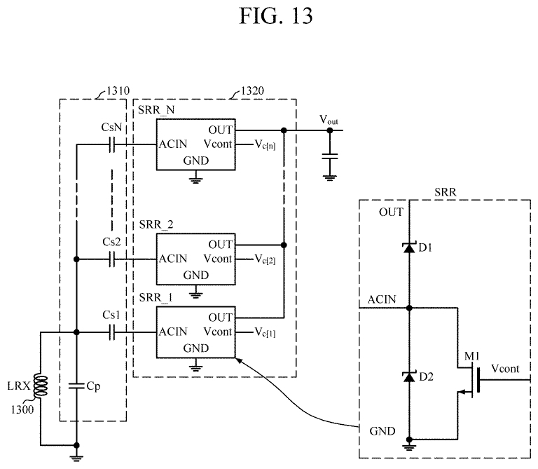

FIG. 13 is a structural diagram illustrating a PRU including an SRR having a parallel structure according to an embodiment of the present invention.

Referring to FIG. 13, the PRU includes a reception antenna LRX 1300, a resonant capacitor network 1310, and an SRR unit 1320 including N SRRs, that is, SRR_1 to SRR_N which are connected in parallel. Each of the SRR_1 to SRR_N may be controlled according to a current required by a load, and thus, an output voltage VOUT may be more precisely controlled. V_{c[1]} to V_{c[n]} are control signals of the SRR_1 to SRR_N. As shown in an enlarged diagram of FIG. 13, the SRR_1 to SRR_N may include a rectifier including D1 and D2 and a switch M1 disposed at a rear end of the rectifier. In order to control the output voltage VOUT using the SRR having the parallel structure, as shown in FIG. 3, capacitors Cs1 to CsN may be required, and in this case, a resonance frequency may satisfy Expression 2 below.

$$f = \frac{1}{2 π \sqrt{LRX \times ( Cp + Cs 1 + Cs 2 + … + CsN )}} . \qquad [ Expression 2 ]$$

In Expression 2, f may be a resonance frequency of the PRU and may match a resonance frequency of a PTU. Since a method of controlling the V_{c[1]} to V_{c[n]} is not directly related to the present invention, detailed descriptions thereof will be omitted.

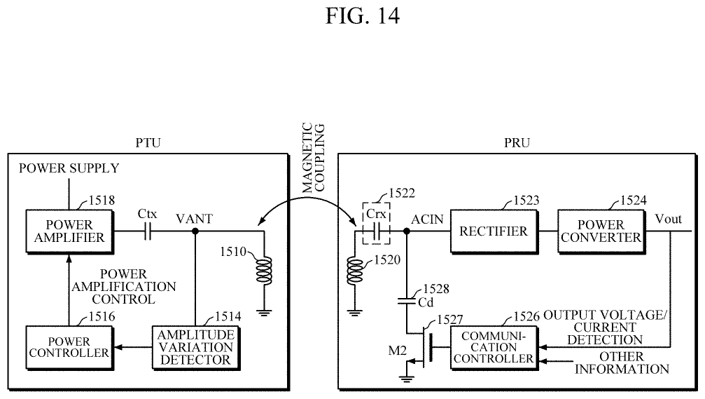

FIG. 14 is a structural diagram illustrating a wireless power system for transmitting and receiving information using an in-band communication method applied to a conventional inductive wireless power transmission system such as a Qi or PMA type.

A PTU and a PRU not only transmit and receive wireless power but also exchange information through communication. For example, the PRU that requires less power may transmit a control signal requesting that the PRU draw a smaller power from the PTU through communication with the PTU. A resonator used to exchange a wireless power signal may also be used to exchange information. In order to perform wireless power transmission, it is necessary to exchange a variety of information between the PTU and the PRU. For example, it is necessary to exchange information on whether the PTU currently requires charging, information on a required charging amount when the PTU currently requires charging, information on a method of adjusting parameters so as to efficiently perform charging, and information on whether charging is completed.

Information may be exchanged by modulating components in the PTU or PRU and sensing the modulation. Resonators may communicate with each other by changing resonator parameters, such as impedance of the resonators, which may affect other resonators in a system. It is possible to enable simultaneous transmission of power and communication signals between the resonators in the wireless power transmission system, or it is possible to enable transmission of power and communication signals during different time periods or at different frequencies using the same magnetic fields that are used during wireless power signal transmission. Communication of information between the resonators may be performed using in-band or out-of-band communication, and when a carrier frequency for an information exchange is close to a resonant frequency used in a power exchange, the communication is referred to as an in-band. Hereinafter, the wireless power system for exchanging information between the PTU and the PRU using the in-band communication will be described with reference to FIG. 14.

The PRU rectifies an AC signal received by a reception antenna 1520 through a rectifier 1523, converts the rectified AC signal into a form of a DC voltage, and converts the converted DC voltage through a DC-DC converter 1524 to output a precise output voltage Vout to be applied to a load. When energy transmitted by the PTU is enough, a voltage/current required by the load may be provided. However, when power supplied by the PTU is small, sufficient power may be not supplied to the load. On the contrary, when the PTU transmits more power than power required by the load of RPU, the wireless power system becomes an inefficient system. Thus, in order to control power of the PRU, the PRU attempts to communicate with the PTU based on a protocol defined between the PRU and the PTU. In this case, a communication signal may be wirelessly exchanged using a transmission antenna 1510 of the PTU and the reception antenna 1520 of the PRU. Such a method is referred to as in-band communication. A Qi or PMA type mainly uses such a method, and the two types use a kind of amplitude modulation.

For communication between the PTU and the PRU, a switch M2 1527 and a capacitor Cd 1528 are required in the PRU. When the switch M2 1527 is turned on, the capacitor Cd 1528 is connected to a reception resonator including the reception antenna 1520 and a resonant capacitor network 1522, and thus, a resonance frequency is changed to change received power. Thus, a current of the reception antenna 1520 varies, the current variation is induced to the transmission antenna 1510 of the PTU which is magnetically coupled with the reception antenna 1520, and thus, a communication signal is transmitted to the transmission antenna 1510. The PTU detects the current variation using an amplitude variation detector 1514 and detects the communication signal to be transmitted by the RPU from the detected variation. Output power of a power amplifier 1518 is controlled through a power controller 1516 according to the detected communication signal.

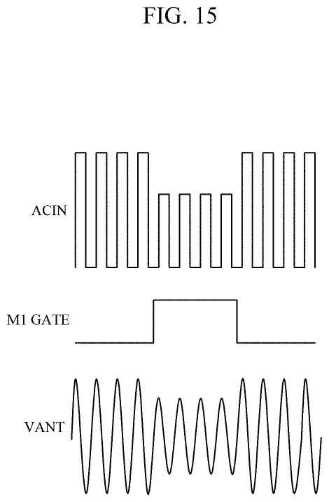

FIG. 15 illustrates operation waveform diagrams of the wireless power system in which information is exchanged through the in-band communication method of FIG. 14.

Referring to FIGS. 14 and 15, when gate input of the switch M2 1527 is set to be high and the switch M2 1527 is turned on, rectifier input ACIN is changed as shown in FIG. 15 by the capacitor Cd 1528. The change also appears in the reception antenna 1520 of the PRU, and similarly, a voltage variation appears even in the transmission antenna 1510 of the PTU. In this way, the PRU may perform digital communication for transmitting and receiving binary signals with the PTU. The PRU may transmit a desired control signal through serial digital communication. Digital information may be transmitted in serial through the serial digital communication.

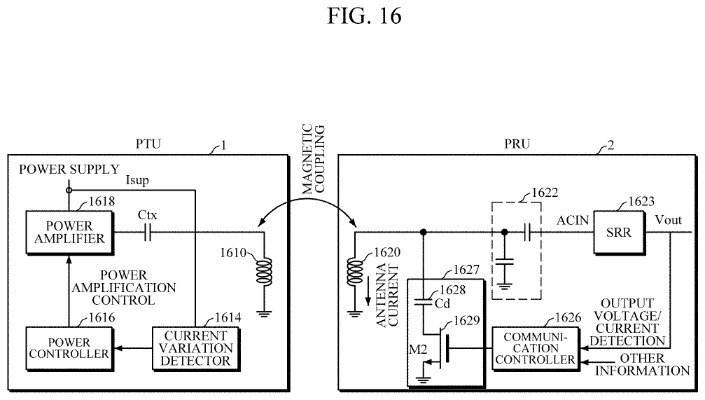

FIG. 16 is a structural diagram illustrating a wireless power system performing in-band communication when an SRR is used according to an embodiment of the present invention.

Unfortunately, wireless power systems including an SRR may not use the method of FIG. 14. Because the SRR uses a method of controlling the rectifier input ACIN to control a rectifier output voltage VOUT, when a switch of the SRR is turned on and the rectifier input ACIN is near a ground potential, a resonator will not react at all even when a switch for communication is turned on. Therefore, a method may not be used in which a current variation of a reception antenna is induced by attaching a capacitor and a communication switch to the rectifier input ACIN to attempt switching. In order to solve such a problem, the present invention proposes a method as shown in FIG. 16.

Referring to FIG. 16, unlike the above described, in a PRU 2, a communication switch M2 1629 and a capacitor Cd 1628 are connected to a reception antenna 1620. In this case, a resonant frequency of a reception antenna 1620 and the capacitor Cd 1628 may be set to be different from the resonant frequency of Expression 1 (the resonant frequency of the reception antenna 1620 and the resonant capacitor network 1622). For example, the resonant frequency of the reception antenna 1620 and the capacitor Cd 1628 may be set to be lower than the resonant frequency of Expression 1. In this case, when the communication switch M2 1629 is turned on, the resonance frequency is greatly lowered and a resonance with a PTU 1 is distorted. Thus, as shown in FIG. 3, a peak of a reception antenna current is lowered. As a result, since power supplied by the PTU 1 is decreased, a current supplied from a power supply of the PTU 1 to a power amplifier 1618 is decreased.

In the PTU 1, a current variation detector 1614 detects a variation of a power supply current Isup, and detects a communication signal in a binary form to be transmitted by the RPU 2 from the detected variation of the current. Output power of the power amplifier 1618 is controlled through a power controller 1616 using the detected communication signal. Like the conventional Qi or PMA, by using such a method, the PRU 2 may control power of the PTU 1 by transmitting a communication signal to the PTU 1 through serial digital communication.

Hereinafter, components of the wireless power system according to the embodiment will be described in detail with reference to FIG. 16.

Referring to FIG. 16, the PRU 2 of the wireless power system, which performs the in-band communication and includes an SRR 1623, includes a reception resonator including the reception antenna 1620 and the resonant capacitor network 1622, the SRR 1623, a frequency adjuster 1627, and a communication controller 1626. The frequency adjuster 1627 may include the capacitor Cd 1628 and the switch M2 1629. Note that there is no power converter from FIG. 15 due to a configuration of the SRR 1623.

The SRR 1623 rectifies a power signal in a form of an AC received from the reception resonator into a power signal in a form of a DC and self-regulates its output voltage without a separate power converter. The SRR 1623 may include a rectifier configured to convert AC power received from the reception resonator into DC power to supply the rectifier output voltage Vout to a load and a low voltage switching element including output terminals connected to an input terminal of the rectifier and a ground and an output terminal to which a control signal generated according to the rectifier output voltage Vout is applied. When the rectifier output voltage VOUT is increased, the low voltage switching element receives a control signal that turns the low voltage switching element on and blocks the rectifier from supplying power to the load, thereby decreasing the rectifier output voltage VOUT. On the contrary, when the rectifier output voltage VOUT is decreased, the low voltage switching element receives a control signal that turns the low voltage switching element off and allows the rectifier to supply power to the load, thereby increasing the rectifier output voltage VOUT. The low voltage switching element may be a MOSFET transistor. However, even when the switching element is replaced by an active element capable of performing a switching operation, for example, a bipolar junction transistor (BJT), a SiC field effect transistor (FET), a GaN FET, or the like, the same function may be performed.

The frequency adjuster 1627 changes a resonance frequency of the reception resonator for in-band communication. The frequency adjuster 1627 may change the resonance frequency of the reception resonator according to a rectifier output voltage and output current controlled by the SRR 1623. In another example, the frequency adjuster 1627 may change the resonance frequency of the reception resonator according to a communication command for exchanging information with the PTU 1. The frequency adjuster 1627 may change the resonance frequency of the reception resonator according to a control signal transmitted from the communication controller 1626 which manages in-band communication.

When the resonant frequency of the reception resonator is changed by the frequency adjuster 1627, a reception antenna current is changed, and the reception resonator transmits a communication signal to the PTU 1 through induction of the changed reception antenna current. The communication signal may include information for adjusting output power of the PTU 1 for optimal wireless power transmission, and other information for in-band communication with the PTU 1, for example, information related to communication performance.

The frequency adjuster 1627 according to the embodiment includes the capacitor Cd 1628 which is connected to the reception antenna 1620 of the reception resonator and changes the resonance frequency of the reception resonator and the communication switch M2 1629 which is connected in series to the capacitor Cd 1628, receives a control, performs switching operation, and controls a change in current of the reception antenna 1620. The communication switch M2 1629 includes a first output terminal connected to the capacitor Cd 1628, a second output terminal connected to the ground, and an input terminal receiving a control signal generated according to the rectifier output voltage Vout. The resonant frequency of the reception antenna 1620 and the capacitor Cd 1628 of the reception resonator may be set to be lower than the resonant frequency of the reception antenna 1620 and the resonant capacitor network 1622 of the reception resonator. The communication switch M2 1629 may be a MOSFET transistor. However, even when the communication switch M2 1629 is replaced by an active element capable of performing a switching operation, for example, a BJT, SiC FET, GaN FET, or the like, the same function may be performed.

The communication controller 1626 generates a control signal for switching the communication switch M2 1629 according to at least one of the rectifier output voltage and output current and other information and transmits the control signal to the communication switch M2 1629. The communication controller 1626 may transmit a control signal for turning the communication switch M2 1629 on to the communication switch M2 1629 and may change a reception current through a change in resonance frequency by the capacitor Cd 1628. Information may be information for adjusting output power of a wireless power transfer unit or other information for in-band communication with the wireless power transfer unit. The information may comply with a communication command for information transmission.

The PTU 1 includes a transmission antenna 1610, the current variation detector 1614, the power controller 1616, and the power amplifier 1618. The transmission antenna 1610 is magnetically coupled with the reception antenna 1620, and a current variation in the reception antenna 1620 is induced thereto. The current variation detector 1614 detects a variation of the power supply current Isup supplied from the power supply to the power amplifier 1618 according to induction of the current variation and detects a digital communication signal from the detected variation of the current. The current variation detector 1614 controls output power of the power amplifier 1618 according to the digital communication signal detected by the current variation detector 1614.

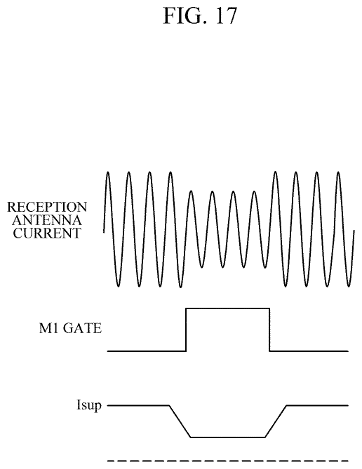

FIG. 17 illustrates operational waveform diagrams of the wireless power system including the SRR of FIG. 16 according to the embodiment of the present invention.

Referring to FIGS. 16 and 17, when the communication switch M2 1629 is turned on, a peak of a current of the reception antenna 1620 is abruptly lowered, and the power supply current Isup of the PTU 1 is lowered.

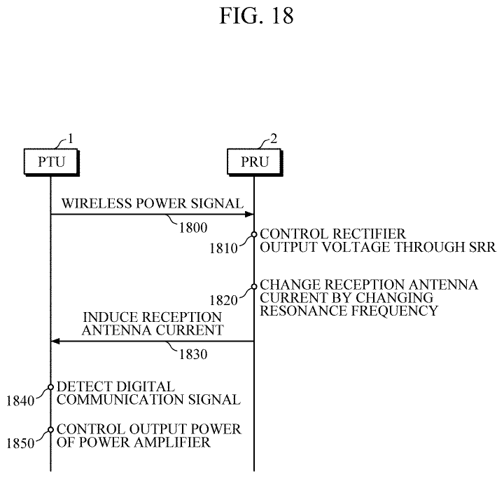

FIG. 18 is a flowchart illustrating an in-band communication method of a wireless power system according to an embodiment of the present invention.

Referring to FIG. 18, a PRU 2 receives a power signal in a form of an AC through a reception antenna of a reception resonator (1800), rectifies the power signal in the form of the AC into a power signal in a form of a DC through a rectifier, and self-regulates a rectifier output voltage through an SRR without a separate power converter (1810). Next, a reception antenna current of the reception resonator is changed by changing a resonance frequency of the reception resonator for in-band communication (1820). According to an embodiment, in the PRU 2, a communication switching element may be turned on by receiving a control signal for in-band communication, and a resonance frequency of a reception antenna may be changed through a capacitor connected to the communication switching element which is turned on. The control signal for the in-band communication may be generated according to at least one of a rectifier output voltage and output current and information to be exchanged with a PTU 1.

A communication signal for adjusting output power of the PTU 1 is transmitted to the PTU 1 through induction of the changed antenna current (1830). Then, a current variation is induced from the reception antenna through a transmission antenna magnetically coupled with the reception antenna, and the PTU 1 detects a variation of a power supply current Isup supplied from a power supply to a power amplifier according to induction of the current variation and detects a digital communication signal from the detected variation of the current (1840). Next, output power of the power amplifier is controlled according to the detected digital communication signal (1850).

So far, the present invention has been described with reference to embodiments thereof. It should be understood by those skilled in the art that various changes in form and details may be made therein without departing from the spirit and scope of the present invention. Therefore, the disclosed embodiments should be considered in a descriptive sense only and not for purposes of limitation. Also, the scope of the present invention is defined not by the detailed description of embodiments but by the appended claims, and all differences within the scope thereof should be construed as being included in the present invention.

1. A wireless power system comprising:
a reception resonator which magnetically resonates with a wireless power transfer unit through a reception antenna;
a self-regulation rectifier which rectifies a power signal in a form of an alternating current (AC) received from the reception resonator into a power signal in a form of a direct current (DC) through a rectifier and self-regulates a rectifier output voltage without a separate power converter; and
a frequency adjuster which changes a resonance frequency of the reception resonator for in-band communication with the wireless power transfer unit,
wherein a reception antenna current is changed according to a change in the resonant frequency, and the reception resonator transmits a communication signal to the wireless power transfer unit through induction of the changed reception antenna current.

2. The wireless power system of claim 1, wherein the frequency adjuster changes the resonance frequency of the reception resonator according to the rectifier output voltage and a rectifier output current controlled by the self-regulation rectifier.

3. The wireless power system of claim 1, wherein the frequency adjuster changes the resonance frequency of the reception resonator according to a communication command for exchanging information with the wireless power transfer unit.

4. The wireless power system of claim 1, wherein the communication signal includes information for adjusting output power of the wireless power transfer unit and other information for in-band communication with the wireless power transfer unit.

5. The wireless power system of claim 1, wherein the frequency adjuster includes a capacitor which is connected to the reception antenna of the reception resonator and changes the resonance frequency of the reception resonator and a communication switching element which is connected in series to the capacitor, receives a control signal, performs switching operation, and controls a change in the reception antenna current.

6. The wireless power system of claim 5, wherein the communication switching element includes a first output terminal connected to the capacitor, a second output terminal connected to a ground, and an input terminal receiving a control signal for in-band communication.

7. The wireless power system of claim 5, wherein a resonance frequency of the reception antenna and a capacitor of the reception resonator when the communication switching element is turned on is different from a resonance frequency of the reception antenna and a resonance capacitor network of the reception resonator when the communication switching element is turned off.

8. The wireless power system of claim 5, further comprising a communication controller which generates a control signal for switching the communication switching element according to at least one of the rectifier output voltage, a rectifier output current, and information to be exchanged with the wireless power transfer unit and transmits the generated control signal to the communication switching element.

9. The wireless power system of claim 1, wherein the self-regulation rectifier includes a rectifier which converts AC power received from the reception resonator into DC power and supplies the rectifier output voltage to a load and a low voltage switching element which includes output terminals connected to a rectifier input terminal and a ground and an output terminal receiving a control signal generated according to the rectifier output voltage.

10. The wireless power system of claim 9, wherein, when the rectifier output voltage is increased, the low voltage switching element receives a control signal for turning the low voltage switching element on, blocks the rectifier from supplying power to the load, and decreases the rectifier output voltage, and when the rectifier output voltage is decreased, the low voltage switching element receives a control signal for turning the low voltage switching element off, allows the rectifier to supply power to the load, and increases the rectifier output voltage.

11. The wireless power system of claim 1, further comprising a transmission antenna which is magnetically coupled with the reception antenna and in which a current variation of the reception antenna is induced thereto, a current variation detector which detects a variation of a power supply current supplied from a power supply to a power amplifier according to induction of the current variation and detects a digital communication signal from the detected current variation, and a power controller which controls output power of the power amplifier according to the digital communication signal detected by the current variation detector.

12. A communication method of a wireless power system, comprising:
receiving, by a wireless power receiving unit, a power signal in a form of an alternating current (AC) through a reception antenna of a reception resonator and rectifying the power signal in the form of the AC into a power signal in a form of a direct current (DC) through a rectifier, wherein a rectifier output voltage is self-regulated without a separate power converter;
changing, by the wireless power receiving unit, a resonance frequency of the reception resonator for in-band communication with a wireless power transfer unit to change a reception antenna current of the reception resonator; and
transmitting, by the wireless power receiving unit, a communication signal to the wireless power transfer unit through induction of the changed reception antenna current.

13. The method of claim 12, wherein the changing of the reception antenna current of the reception resonator includes receiving, by a communication switching element, a control signal for the in-band communication to be turned on and changing a resonant frequency of the reception antenna through a capacitor connected to the communication switching element which is turned on.

14. The method of claim 13, wherein the control signal for the in-band communication is generated according to at least one of the rectifier output voltage, a rectifier output current, and information to be exchanged with the wireless power transfer unit.

15. The method of claim 12, wherein an in-band communication method in the wireless power system further includes inducing, by the wireless power transfer unit, a current variation from the reception antenna through a transmission antenna magnetically coupled with the reception antenna, detecting, by the wireless power transfer unit, a variation of a power supply current supplied from a power supply to a power amplifier according to induction of the current variation and detecting a digital communication signal from the detected variation of the power supply current, and controlling, by the wireless power transfer unit, output power of the power amplifier according to the detected digital communication signal.
